(19) United States
(12) Patent Application Publication
(10) Pub. No.: US 2007/0195386 A1
(43) Pub. Date: Aug. 23, 2007

(54) Display processing device, display processing method, and computer program product

(76) Inventors: Michinari Shinohara, Kanagawa (JP); Hiroshi Morikawa, Kanagawa (JP)

Correspondence Address: COOPER & DUNHAM, LLP, 1185 AVENUE OF THE AMERICAS, NEW YORK, NY, 10036, US

(21) Appl. No.: 11/704,882

(22) Filed: Feb. 8, 2007

(30) Foreign Application Priority Data
Feb. 20, 2006 (JP) 2006-043173

(51) Int. Cl. G03F 3/10

(52) U.S. Cl. 358/527

(57) ABSTRACT

A display processing unit displays a setting item for an image processing and preview information indicating an overview of a result of the image processing using the setting item on a screen of a displaying unit. A selection receiving unit receives a selection of an arbitrary setting item from among setting items displayed on the screen. The display processing unit changes the preview information based on an overview of a result of the image processing using a setting item changed by a user or a setting item for which the selection is received, and displays changed preview information on the screen.

### CROSS-REFERENCE TO RELATED APPLICATIONS

The present document incorporates by reference the entire contents of Japanese priority document, 2006-043173 filed in Japan on Feb. 20, 2006.

### BACKGROUND OF THE INVENTION

1. Field of the Invention

The present invention relates to a technology for displaying an operation display for setting and executing functions.

2. Description of the Related Art

In recent years, image forming apparatuses having functions of devices, such as a printer, a copier, a facsimile machine, and a scanner, accommodated in one box (a multifunction product (MFP)) have been known. In this MFP, a displaying unit, a printing unit, and an image-pickup unit are provided within one box, and pieces of software corresponding to the printer, the copier, and the facsimile machine are respectively provided. By switching among these pieces of software, the MFP is caused to operate as a printer, a copier, and a facsimile machine.

In such a conventional MFP, for setting at the time of executing various functions mentioned above, a display operating unit is provided, such as a liquid crystal touch panel. In MFPs of recent years, a plurality of functions are present, and many items have to be set. Therefore, displaying a setting screen that is easy to understand and reducing a setting operation load on users are desired.

On the other hand, an exemplary scheme has been realized in which, instead of displaying all setting items of a plurality of functions on one screen, various setting screens for the respective functions are switched for display by selecting a predetermined button or tab.

Furthermore, for example, Japanese Patent Application Laid-Open No. 2005-184860 suggests a technology in which, with commonality of screen displays for setting items of the respective functions each handling a similar operation, an operating unit that is easy to operate and understand can be provided even if switching is made among the setting screens for each function.

However, in the method disclosed in Japanese Patent Application Laid-Open No. 2005-184860, it is difficult to check what output will finally be obtained when a process, such as printing, is performed with the set conditions. Also, even though a technology for preview display of the output result has been developed, if a different setting screen is provided for each screen, a preview display is displayed for each setting screen. To check the output results of the plurality of functions, screen switching is required, thereby increasing an operation load.

### SUMMARY OF THE INVENTION

It is an object of the present invention to at least partially solve the problems in the conventional technology.

A display processing device according to one aspect of the present invention includes a display processing unit that displays a setting item for an image processing and preview information indicating an overview of a result of the image processing using the setting item on a screen of a displaying unit; and a selection receiving unit that receives a selection of an arbitrary setting item from among setting items displayed on the screen. The display processing unit changes the preview information based on an overview of a result of the image processing using a setting item changed by a user or a setting item for which the selection is received, and displays changed preview information on the screen.

A display processing method according to another aspect of the present invention includes displaying a setting item for an image processing and preview information indicating an overview of a result of the image processing using the setting item on a screen of a displaying unit; and receiving a selection of an arbitrary setting item from among setting items displayed on the screen. The displaying includes changing the preview information based on an overview of a result of the image processing using a setting item changed by a user or a setting item for which the selection is received, and displaying changed preview information on the screen.

A computer program product according to still another aspect of the present invention includes a computer-usable medium having computer-readable program codes embodied in the medium that when executed cause a computer to execute displaying a setting item for an image processing and preview information indicating an overview of a result of the image processing using the setting item on a screen of a displaying unit; and receiving a selection of an arbitrary setting item from among setting items displayed on the screen. The displaying includes changing the preview information based on an overview of a result of the image processing using a setting item changed by a user or a setting item for which the selection is received, and displaying changed preview information on the screen.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a functional block diagram of an MFP capable of performing functions of a display processing device according to a first embodiment of the present invention;

FIG. 2 is a drawing depicting one example of an operation panel of the MFP;

FIG. 3 is a flowchart of an entire flow of a display process;

FIG. 4 is a drawing for explaining one example of an initial screen;

FIG. 5 is a drawing for explaining one example of a login screen;

FIG. 6 is a drawing for explaining one example of a Home screen;

FIG. 7 is a drawing for explaining one example of a Functions screen;

FIG. 8 is a drawing for explaining one example of a Job screen;

FIG. 9 is a drawing for explaining one example of a History screen;

FIG. 10 is a drawing for explaining one example of a job execution screen;

FIG. 11 is a drawing for explaining one example of a state display screen;

FIG. 12 is a drawing for explaining one example of a check screen;

FIG. 13 is a drawing for explaining one example of a setting change screen;

FIG. 14 is a drawing for explaining one example of a detail setting screen;

FIG. 15 is a drawing for explaining one example of the Job screen after a new job is added;

FIG. 16 is a drawing for explaining one example of a job creation screen;

FIG. 17 is a drawing for explaining one example of a list display screen;

FIG. 18 is a drawing for explaining one example of a detailed history screen;

FIG. 19 is a drawing for explaining another example of the initial screen;

FIG. 20 is a drawing for explaining one example of a login screen;

FIG. 21 is a drawing for explaining another example of the detail setting screen;

FIG. 22 is a drawing for explaining one example of a detail setting screen in which the details are selectable;

FIG. 23 is a drawing for explaining one example of a detail setting screen in which a preview image is displayed;

FIG. 24 is a drawing for explaining one example of a detail setting screen after selection of all setting items has been completed;

FIG. 25 is a drawing for explaining one example of a job creation screen after function addition;

FIG. 26 is a drawing for explaining one example of a name input screen;

FIG. 27 is a drawing for explaining one example of a Job screen after a new job is added;

FIG. 28 is a drawing for explaining one example of an eDocuments screen;

FIG. 29 is a drawing for explaining one example of an eDocuments screen after a thumbnail image is added;

FIG. 30 is a drawing for explaining one example of an eDocuments screen in which thumbnail images are reduced and displayed;

FIG. 31 is a drawing for explaining one example of an eDocuments screen in which thumbnail images are enlarged and displayed;

FIG. 32 is a block diagram of a hardware configuration of the MFP according to the first embodiment; and

FIG. 33 is a function block diagram of a display processing device according to a second embodiment of the present invention.

### DETAILED DESCRIPTION OF THE PREFERRED EMBODIMENTS

Exemplary embodiments of the present invention are explained in detail below with reference to the accompanying drawings.

A display processing device according to a first embodiment of the present invention displays a preview that depicts image process results of the selected setting item on a screen for selecting a setting item. Also, when a plurality of image processes are concurrently executed, previews for the respective image processes are simultaneously displayed.

According to the first embodiment, the case in which the present invention is applied to an MFP, which is one type of image forming apparatus, is explained. However, the present invention is not meant to be restrictive, and can be applied to various apparatus for display processing.

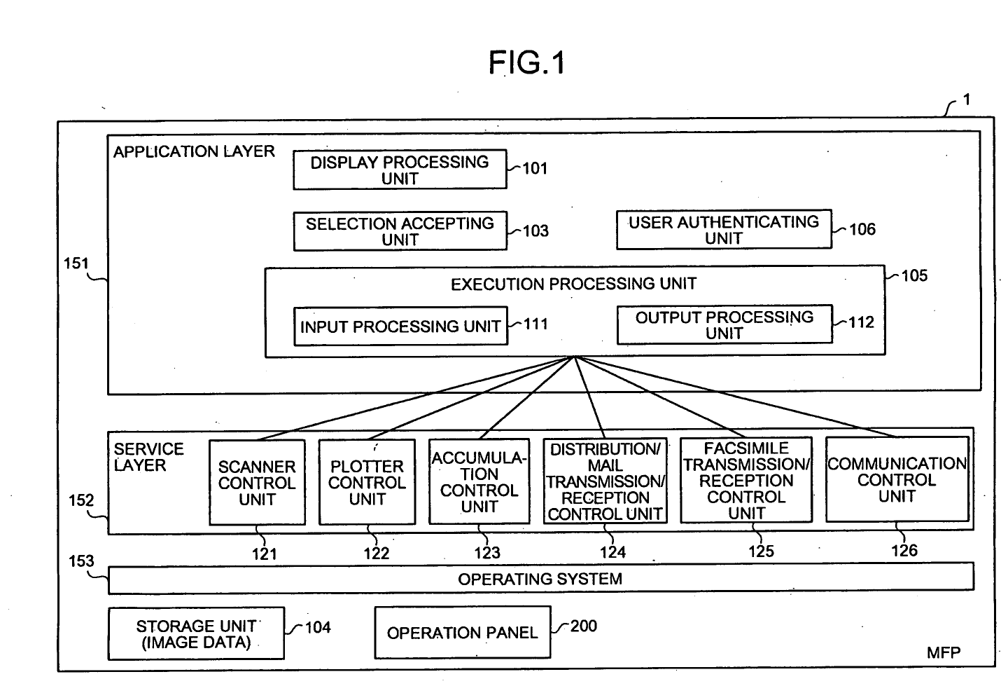

FIG. 1 is a functional block diagram of an MFP 1 capable of performing functions of a display processing device according to the first embodiment. As depicted in the drawing, the MFP 1 includes, as components, an operating system 153, a service layer 152, an application layer 151, a storage unit 104, and an operation panel 200.

As depicted in the drawing, the functions of the MFP 1 have a hierarchical relation in which the operation system 153 has an upper layer on which the service layer 152 is configured, and the service layer 152 has an upper layer on which the application layer 151 including a feature of the first embodiment is configured.

The operating system 153 manages resources of the MFP 1 including hardware resources, and provides functions using these resources to the service layer 152 and the application layer 151.

The service layer 152 corresponds to a driver that controls the hardware resources included in the MFP. In response to a request from an output process from an execution processing unit 105 of the application layer 151, which will be explained further below, the hardware resources included in the MFP 1 are controlled from a scanner control unit 121, a plotter control unit 122, an accumulation control unit 123, a distribution/mail transmission/reception control unit 124, a facsimile transmission/reception control unit 125, a communication control unit 126, and other units, thereby causing various functions to be executed.

The storage unit 104 stores image data read from a paper document or received through mail or facsimile. Also, the storage unit 104 is a storage unit capable of storing data, such as image data, and can be configured of any storage medium that can be generally used, such as a hard disk drive (HDD), an optical disk, or a memory card.

The operation panel 200 is a user interface that displays an operation screen and receives inputs on an operation screen.

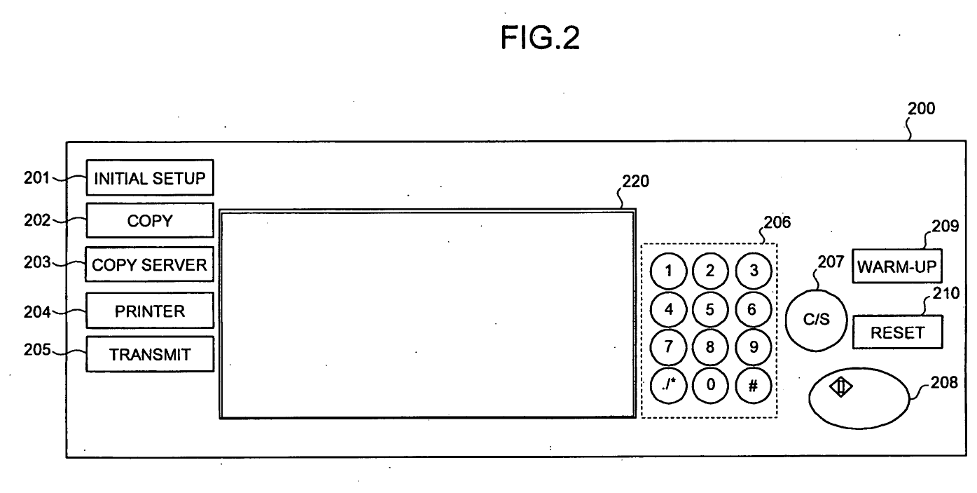

FIG. 2 is a drawing depicting one example of the operation panel 200 of the MFP 1. As depicted in the drawing, the operation panel 200 includes an Initial setup key 201, a Copy key 202, a Copy server key 203, a Printer key 204, a Transmit key 205, a numeric keypad 206, a Clear/stop key 207, a Start key 208, a Warm-up key 209, a Reset key 210, and a liquid-crystal-display (LCD) touch panel 220. On the LCD touch panel 220, a screen, which is a feature of the first embodiment, is displayed. This screen will be explained further below.

In addition to the storage unit 104 and the operation panel 200, the MFP 1 also includes various hardware resources, such as a scanner and a plotter, but their explanation is omitted herein.

Referring back to FIG. 1, the application layer 151 includes a display processing unit 101, a selection receiving unit 103, the execution processing unit 105, and a user authenticating unit 106.

The user authenticating unit 106 authenticates the user when using the MFP 1. Any user authentication method may be used irrespectively of whether the method is known to the person skilled in the art. When the user authentication at the user authenticating unit 106 is successful, the use of a predetermined function in the MFP 1 is allowed. An example of the function to be allowed is transmission and reception of e-mails. It is also assumed that user authentication by the user authenticating unit 106 is performed first and, in principle, user authentication has been completed by the time when the function that will be explained further below is used.

The display processing unit 101 causes an operation screen for executing various functions or setting the setting items to be displayed on the LCD touch panel 220. According to the first embodiment, the display processing unit 101 causes a preview of the image process result with the selected setting items to be displayed on the same screen together with the setting items to be selected. Also, when a setting item is changed, a preview on which the changed setting item is reflected is instantaneously displayed on the screen.

The selection receiving unit 103 receives, from the screen caused to be displayed by the display processing unit 101, a selection in the area in which the setting items are indicated. Specifically, when the user presses a setting item caused to be displayed by the display processing unit 101 on the LCD touch panel 220, the selection receiving unit 103 receives that the setting item has been selected. Also, the selection receiving unit 103 receives inputs from various buttons, such as the Initial setup key 201, which will be explained further below.

The execution processing unit 105 includes an input processing unit 111 and an output processing unit 112 for input and output processing using the functions included in the MFP 1. Based on the process results at the execution processing unit 105, each control unit included in the service layer 152 controls the hardware resource. With this, processing using hardware is performed.

The input processing unit 111 performs an input process on image data using an input function corresponding to the setting item whose selection is received by the selection receiving unit 103. For example, when the selection receiving unit 103 receives selection of a setting item of “Copy”, the input processing unit 111 controls a scanner not shown through the scanner control unit 121, thereby causing a process of reading a paper document to be performed.

The output processing unit 112 performs an output process on image data using an output function corresponding to the setting item whose selection is received by the selection receiving unit 103. For example, when the selection receiving unit 103 receives selection of a setting item of “Copy”, the output processing unit 112 controls a plotter not shown through the plotter control unit 122, thereby causing a process of printing a paper document to be performed.

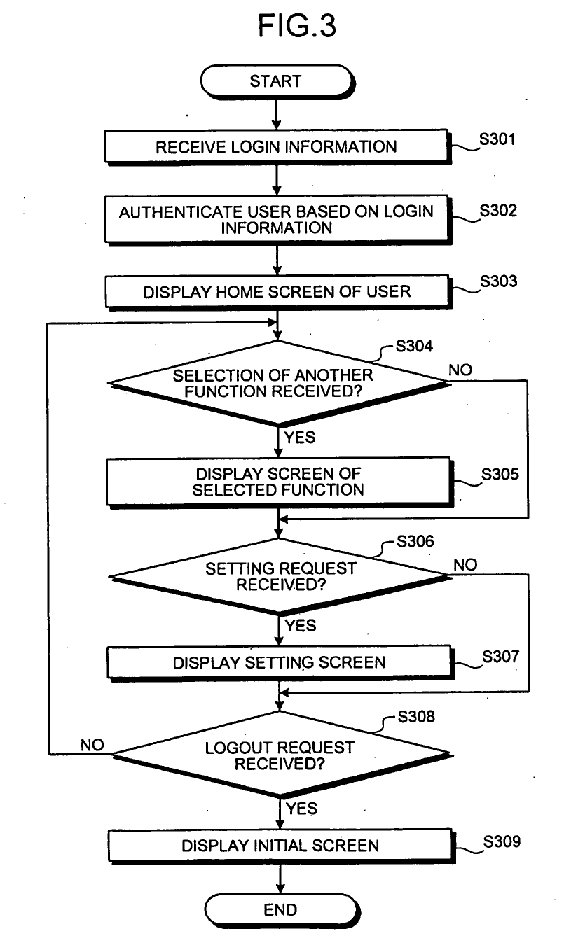

FIG. 3 is a flowchart of an entire flow of the display process in the first embodiment. The selection receiving unit 103 receives login information input from the user (step S301). Specifically, the selection receiving unit 103 receives a user name and password input on a login screen (that will be explained further below) as login information. The login screen is displayed when the user selects a button for login displayed on an initial screen (that will be explained further below).

The user authenticating unit 106 authenticates the user based on the login information received by the selection receiving unit 103 (step S302).

The display processing unit 101 causes a Home screen of the logged-in user to be displayed on the LCD touch panel 220 (step S303). The Home screen is a screen first displayed after login, on which functions defined for each user and used with high frequency are registered. Details about Home screen will be explained further below.

The selection receiving unit 103 determines whether selection of another function has been received (step S304). Another function is a function for displaying, for example, a Job screen that displays a Job in which a routine process is defined, a Functions screen that displays individual functions of the MFP 1 (such as copy and facsimile transmission), and a History screen that displays process history.

If another function has been received (Yes at step S304), the display processing unit 101 causes a screen corresponding to the selected function to be displayed on the LCD touch panel 220 (step S305).

If another function has not been received (No at step S304), the selection receiving unit 103 determines whether a setting request has been received (step S306). The setting request is a request for changing as setting item when individual functions of the MFP 1 is executed or a request for changing a setting item selected on the screen.

If a setting request has been received (Yes at step S306), the display processing unit 101 causes a setting screen for changing the setting item to be displayed on the LCD touch panel 220 (step S307). Here, in the case of a setting request for changing the setting item already displayed, a new setting screen is not displayed. In that case, the display processing unit 101 only changes the setting item displayed on the screen.

If a setting request has not been received (No at step S306), the selection receiving unit 103 determines whether a logout request has been received (step S308). The logout request is received when a button for logout displayed on a lower portion of the screen is selected.

If a logout request has not been received (No at step S308), the procedure returns to a selection receiving process for another function, thereby repeating the processes explained above (step S304).

If a logout request has been received (Yes at step S308), the display processing unit 101 causes the initial screen before login to be displayed (step S309).

In this manner, according to the first embodiment, after user's login, various screens are displayed according to the function selected by the user or the setting request. Details about each screen and screen transition will be explained below.

In screen transition among the screens, a screen transition process is executed according to the flowchart of FIG. 3, in which another screen is displayed according to the selection of a function on an arbitrary screen.

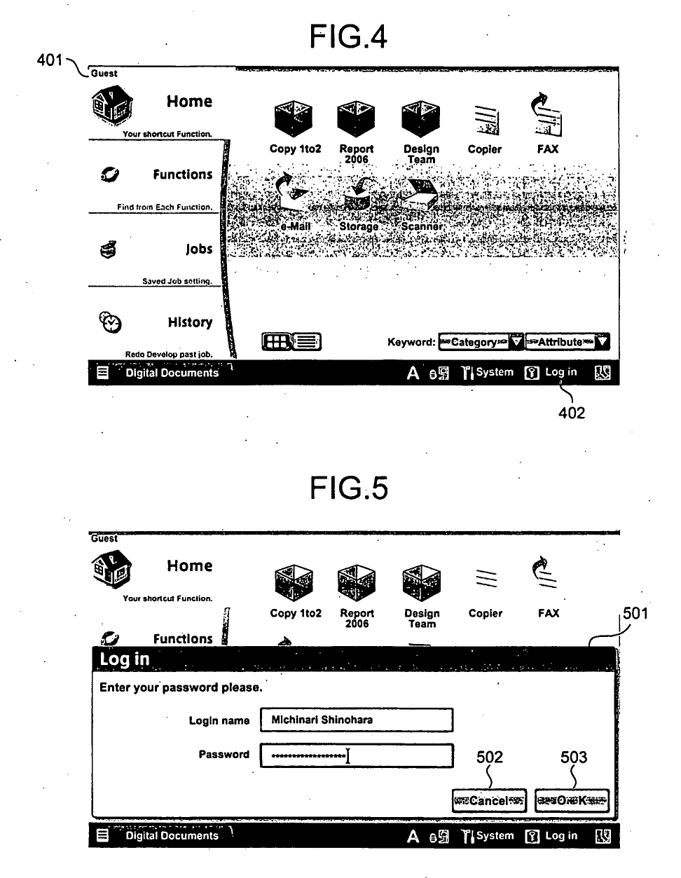

FIG. 4 is a drawing for explaining one example of the initial screen. As depicted in the drawing, the screen is displayed on the initial screen in the state where Home is selected from among four functions (Home, Jobs, Functions, and History). Also, on the left side of the screen, an initial screen display 401 (Guest) indicating that these functions can be used in common by all users is presented.

Also, on a portion on the right of the center portion of the screen, a plurality of setting items indicative of selectable setting functions are displayed. In the drawing, as functions usable in common, copy (Copier), facsimile transmission (FAX), and others are displayed.

The rendering attributes of the initial screen, such as background color, may be configured to be different from rendering attributes of each screen after the user logs in, which will be explained further below. With this, it can be clearly known that the user is in a state before login.

As shown in the drawing, on the initial screen, in addition to Home, Jobs, Functions, and History are displayed in a tab format. To prevent these functions from being used on the initial screen, these functions may be configured to be unselectable.

Upon selection of a Login button 402 (Login) displayed on the lower-right portion of the drawing, a login screen is displayed.

FIG. 5 is a drawing for explaining one example of the login screen. As depicted in the drawing, on the login screen, an input area 501 is displayed on a lower portion of the screen on which a login user name (Login name) and a password (Password) are to be entered.

When a Cancel button 502 (cancel) in the input area 501 is selected, the screen returns to the initial screen. When the user name and the password are entered in the input area and an OK button 503 is pressed, the Home screen defined for each user is displayed.

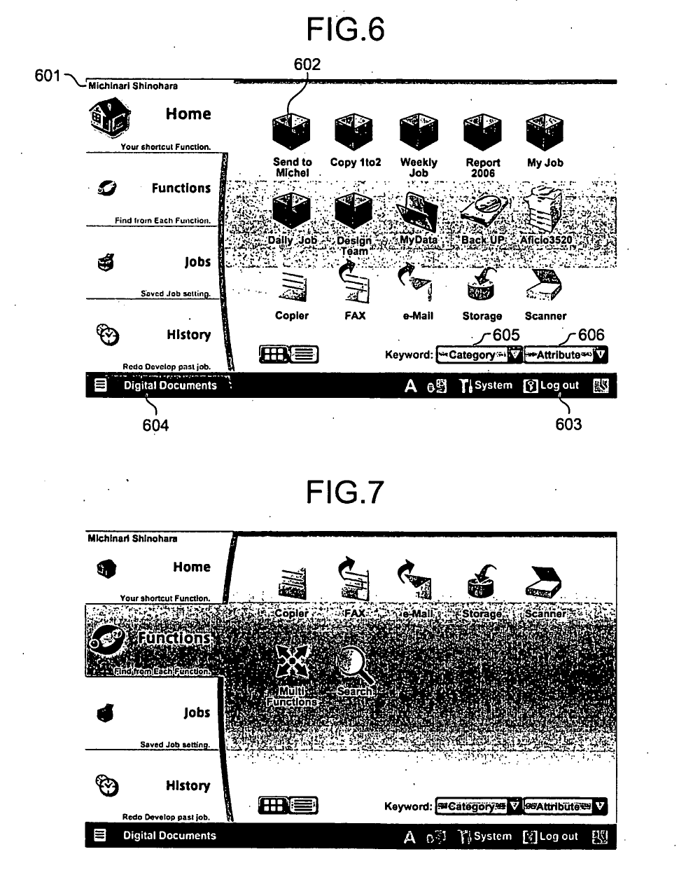

FIG. 6 is a drawing for explaining one example of the Home screen. As depicted in the drawing, on the Home screen, instead of the initial screen display 401, a display 601 indicating the name of the user who has logged in is presented. Also, on a right portion of the center portion of the screen, a plurality of setting items defined for each logged-in user are displayed.

On the Home screen, the tabs corresponding to the functions other than Home, that is, Jobs, Functions, and History, are selectable. When the tab of another function is selected, setting items corresponding to the selected function are displayed on the right portion of the center portion of the screen.

In this manner, according to the first embodiment, items to be selected or set are displayed in a vertical hierarchical structure. For example, in FIG. 6, the Home tab is an upper setting item. With respect to the upper setting item, an item 602 (Send to Michel), for example, is displayed as a sub-setting item.

On a lower portion of the drawing, a Logout button 603 for executing logout is displayed. When the logout button 603 is selected, the screen makes a transition to the initial screen.

On a lower-left portion of the drawing, a Digital document button 604 is displayed for displaying an eDocuments screen on which a document is specified as an input source. As explained further below, this button is displayed on any screen corresponding to the relevant one of the four functions explained above, and is selectable. With this, the user can easily specify the input source document at the time of executing any function.

On a lower-right portion of the drawing, a category list 605 and an attribute list 606 are displayed for narrowing down setting items. On the category list 605 and the attribute list 606, a category and an attribute representing the contents of the setting item previously defined can be specified, respectively. When the specification of the category list 605 and the attribute list 606 is changed, only the setting item applicable to the specified category and attribute is displayed to be selectable.

The Home screen first displayed after login has been explained above. The user can select another function from out of the functions, such as Job, Functions, and History, and can display the corresponding screen, such as a Job screen, a Functions screen, or a History screen. Here, these functions are not meant to be restrictive, and the present invention can be configured so that any other functions can be set and selected.

FIG. 7 is a drawing for explaining one example of the Functions screen. As shown in FIG. 7, the Functions screen has a configuration similar to that of the Home screen, except that only the individual functions, such as the copy function and the facsimile transmission function are selectable. The individual functions are represented by predefined icons. Here, the icons mean pictures or pictographs displayed on a display screen for representing various data and processing functions.

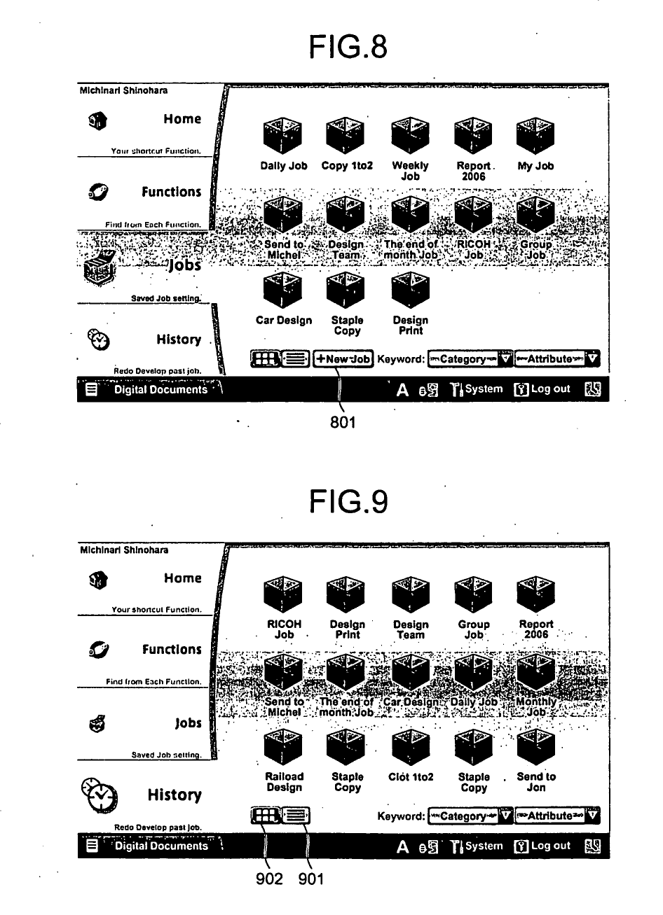

FIG. 8 is a drawing for explaining one example of the Job screen. As depicted in the drawing, the Job screen has a configuration similar to that of the Home screen except that only the functions defining routine processes are selectable. According to the first embodiment, the jobs are represented by cubic-shaped icons. Also, a New job button 801 for creating a new job is displayed. Details about new job creation will be explained further below.

FIG. 9 is a drawing for explaining one example of the History screen. As depicted in the drawing, the History screen has a configuration similar to that of the Home screen except that the history of previous processes are selectable. On a screen where a plurality of icons of functions are displayed, such as on the History screen, a List display button 901 and an Icon display button 902 are displayed. By selecting either one of the List display button 901 and the Icon display button 902, the display format can be interchanged. Details about a display format changing process will be explained further below.

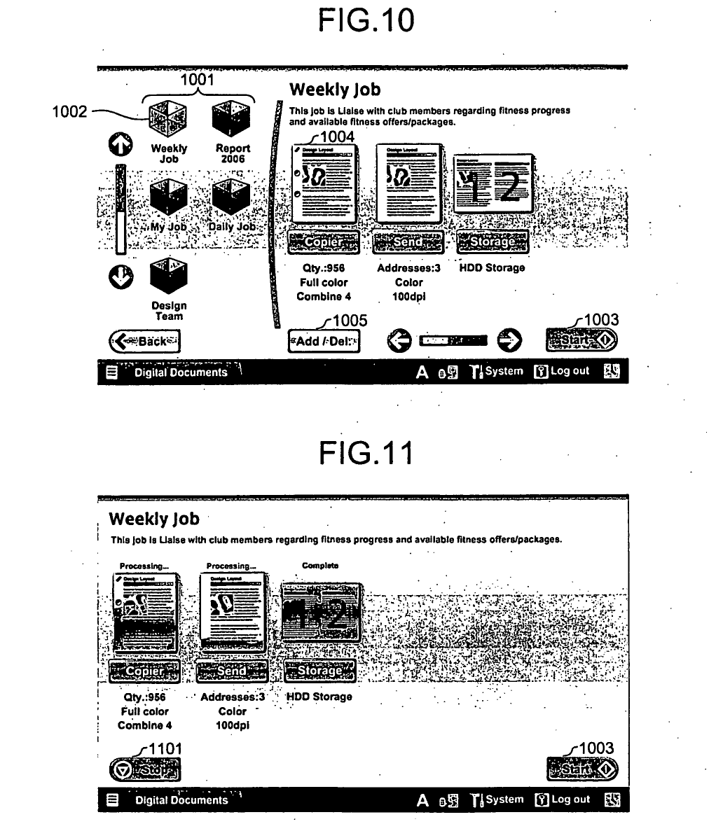

FIG. 10 is a drawing for explaining one example of a job execution screen displayed when a job is selected within the Home screen or the Job screen. According to the first embodiment, when a job is selected, the original Home screen or the Job screen is scrolled in a left direction to be moved outside of the display area of the LCD touch panel 220. Also, the job execution screen is scrolled from a right direction to be displayed within the display area of the LCD touch panel 220. That is, the Home screen, for example, on which upper setting items are displayed, and the job execution screen, which relates to sub-setting items selected from the upper setting items, are displayed on different screens.

As depicted in the drawing, part of the setting items displayed on the previous screen (according to the first embodiment, the job icons) are displayed in an area 1001 on the left side of the center portion of the screen. Furthermore, the color of an icon 1002 of the selected job is changed to a color that is different from other icons for display. With this, the user can clearly understand the processing state and the job currently being set.

In the drawing, as routine processes to be weekly performed (Weekly Job), jobs of copy, mail transmission, and storing documents in the HDD are exemplarily depicted. Also, for each function, a preview image indicating a summary of the process result is displayed.

When a Start button 1003 is selected on the job execution screen, processing the displayed job is started, thereby causing a state display screen to be displayed.

FIG. 11 is a drawing for explaining one example of the state display screen. As depicted in the drawing, on the state display screen, the progress of each function that configures a job is represented by an area covering the preview image with a blue translucent image.

As in the example depicted in the drawing, when a plurality of functions are registered for one job, the progresses of the respective functions can be simultaneously checked on the screen. Here, the scheme of displaying the progress is not meant to be restricted to the above, but any scheme conventionally used can be applied, such as a scheme of displaying the progress by a graph or numerical value indicating the progress for each function.

When a Stop button 1101 is selected, the job processing being executed is suspended. For restart, the start button 1003 is again selected.

Referring back to the job execution screen of FIG. 10, when a preview image 1004 in the drawing is selected, a check screen is displayed in which a preview is enlarged for display.

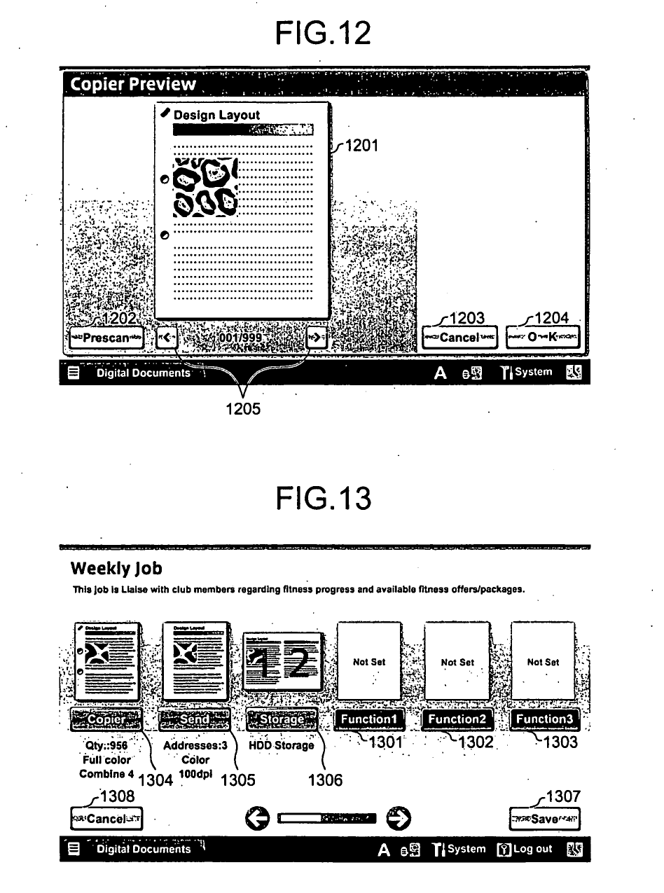

FIG. 12 is a drawing for explaining one example of the check screen. As depicted in the drawing, on the check screen, a preview image 1201 is displayed as being enlarged. With this, the user can clearly check, for example, the position of punched holes.

When a Prescan button 1202 is selected, the document is scanned in advance (prescanned) before job execution, thereby allowing a preview of the process result to be checked on the screen. When a Cancel button 1203 is selected, prescan is cancelled, and then the screen returns to the original screen. When an OK button 1204 is selected, the screen returns to the job execution screen that displays a preview image to which the image of the prescanned document is applied. At this time, the prescanned image is stored in a random access memory (RAM) or the like, and when the selection of the OK button is received, the stored information is passed to the next screen.

When the document containing a plurality of pages is scanned, with the selection of one of arrow buttons 1205, the preview image of the previous or next page can be checked.

Referring back to the job execution screen of FIG. 10, when an Add/delete button 1005 is selected, a setting change screen for changing the job settings is displayed.

FIG. 13 is a drawing for explaining one example of the setting change screen. As depicted in the drawing, on the setting change screen, in addition to the preview images displayed on the job execution screen, function buttons 1301, 1302, and 1303 for adding a new function are displayed. When any one of the function buttons 1301, 1302, and 1303 is selected or when any one of buttons 1304, 1305, and 1306 under the preview images is selected, a detail setting screen for setting a new function or changing the existing function is displayed.

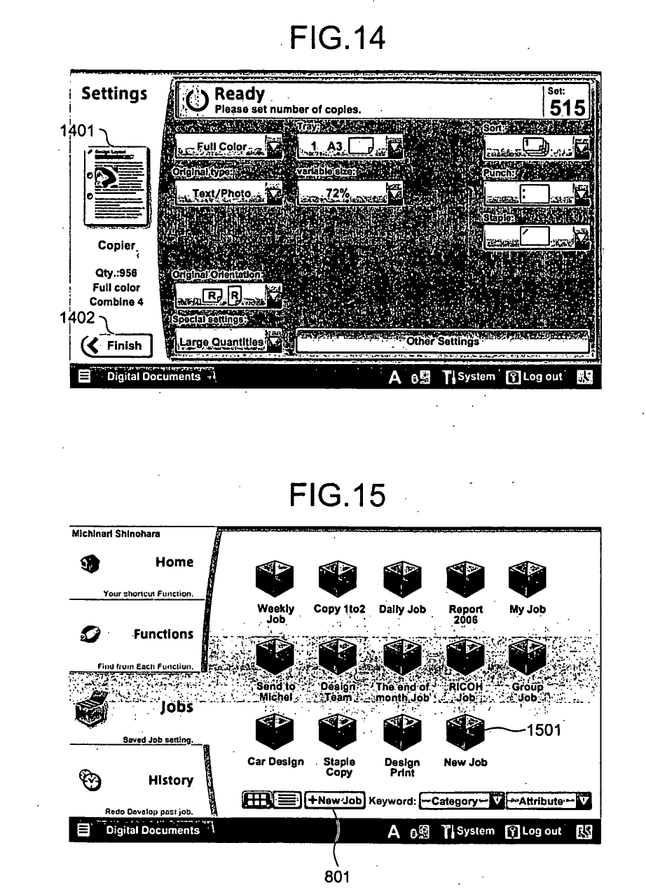

FIG. 14 is a drawing for explaining one example of the detail setting screen. In this drawing, one example of the detail setting screen for changing the settings of the copy function displayed when the button 1304 of FIG. 13 is selected. As depicted in FIG. 14, on the detail setting screen, the detailed setting items regarding the copy function are displayed.

In the drawing, for example, as detailed setting items, color, tray, scaling factor, sorting, punching, and others are exemplarily displayed as being changeable by the user.

On the detail setting screen, a preview 1401 depicting an example of an image to which the detailed setting items are applied is displayed in a left area of the screen. Furthermore, on the detail setting screen, the preview 1401 on which a changed setting is reflected is displayed at the same time when a setting is changed. With this, the user can instantaneously and visually recognize the changed setting.

When a Finish button 1402 is selected, the setting item setting process is completed, and the screen then returns to the setting change screen. Also, when a Save button 1307 on the setting change screen of FIG. 13 is selected, the changed setting is saved, and the screen then returns to the Job screen. Here, at the time of saving, either overwriting the existing job for update or saving the settings as a new job can be selected. Also, when a Cancel button 1308 in FIG. 13 is selected, the changed setting is discarded, and the screen then returns to the previous screen.

FIG. 15 is a drawing for explaining one example of the Job screen after a new job is added. On the Job screen, an icon 1501 of the job newly created is displayed with color different from that of the existing jobs (not shown). Here, after a predetermined time is elapsed, the color of the icon 1501 of the newly-created job is changed to the color of the existing icons.

When the new job button 801 in FIG. 8 or FIG. 15 is selected, a job creation screen for creating a new job is displayed.

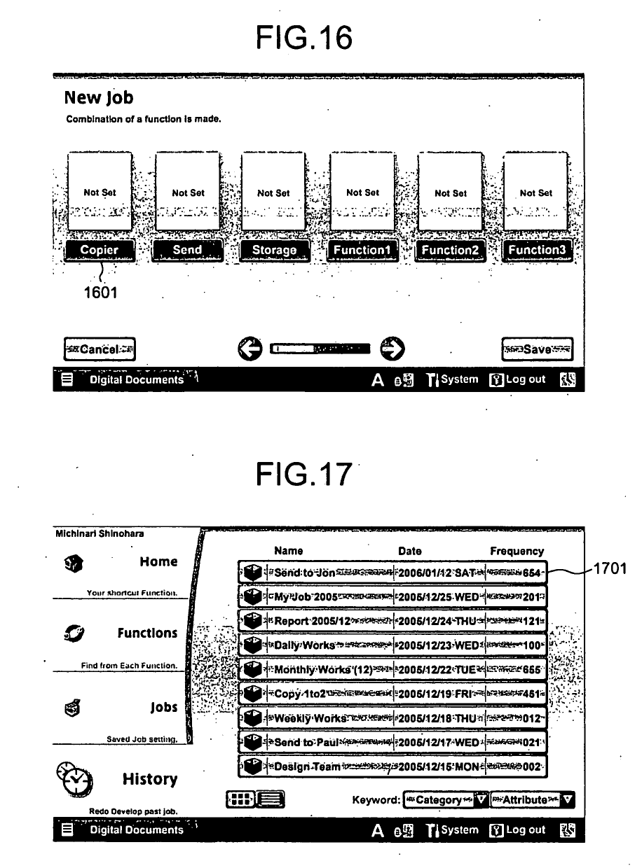

FIG. 16 is a drawing for explaining one example of the job creation screen. As depicted in the drawing, the job creation screen has a configuration similar to that of the setting change screen of FIG. 13, but a screen in which any function is not set is displayed. Details about a new job creating process are explained further below.

Referring back to FIG. 9, the details about the display format changing process are explained. When the List display button 901 is selected, a list display screen is displayed on which identification information, such as history name, is displayed in an at-a-glance format (list format).

FIG. 17 is a drawing for explaining one example of the list display screen. As depicted in the drawing, on the list display screen, information about history names, process dates, frequencies, and others are displayed in an at-a-glance format. Here, for example, when a history 1701 is selected, a detailed history screen on which detailed information about the selected history 1701 can be checked is displayed.

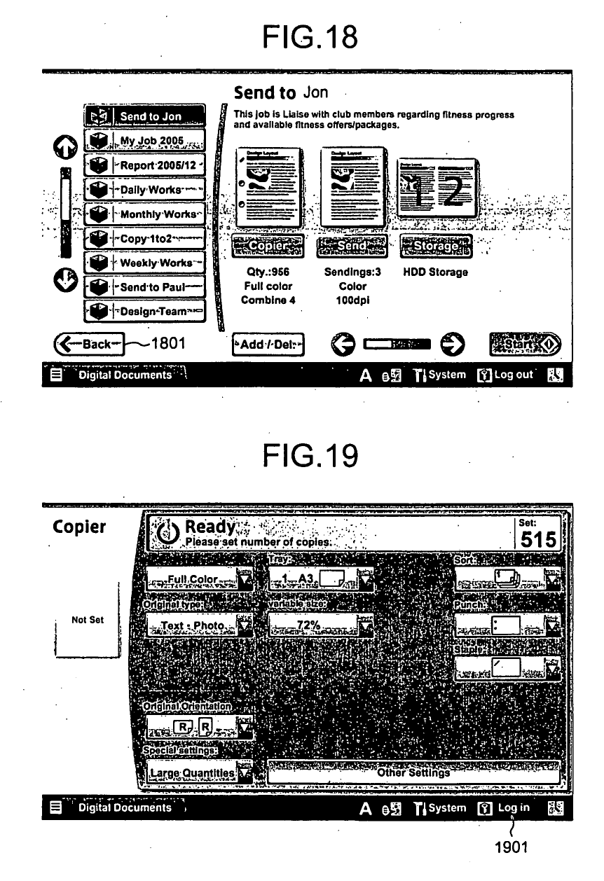

FIG. 18 is a drawing for explaining one example of the detailed history screen. As depicted in the drawing, on the detailed history screen, the preview screen displaying the execution result of the job can be checked, for example. When a Back button 1801 is selected, the screen returns to the list display screen.

Transitions of main screens displayed on the MFP 1 according to the first embodiment have been explained. In the explanation above, the screen as depicted in FIG. 4 is displayed as an initial screen. However, the initial screen is not meant to be restricted such a screen, and a screen arbitrarily selected by the user can be displayed as an initial screen.

FIG. 19 is a drawing for explaining another example of the initial screen. In this drawing, the execution screen of the copy function most frequently used by the user is exemplarily displayed as an initial screen. Even in the case of such an initial screen as that of FIG. 19, a login screen can be displayed with the selection of a Login button 1901.

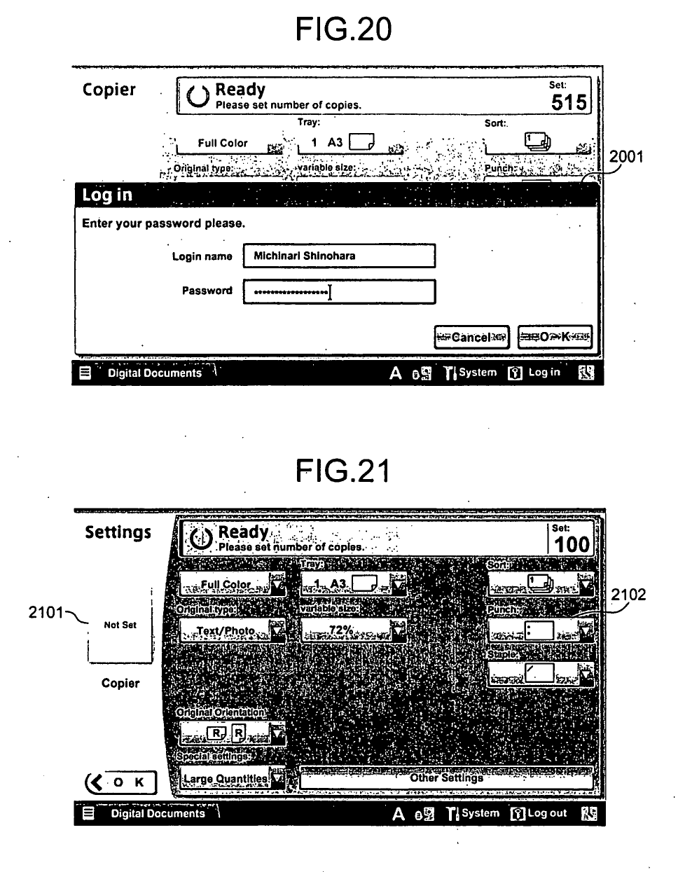

FIG. 20 is a drawing for explaining one example of the login screen displayed in this example. As depicted in the drawing, on the login screen, an input area 2001 in which a login user name (Login name) and a password (Password) are to be entered is displayed on a lower portion of the screen.

The configuration of the input area 2001 and the process after button selection are similar to those of the input area 501 in FIG. 5, and therefore are not explained herein.

Even when the icon of the copy function is selected on such an initial screen as depicted in FIG. 4, a screen for setting detailed items of the copy function as depicted in FIG. 19 is displayed.

In FIG. 16, for example, when a button 1601 corresponding to the copy function is selected, a detail setting screen similar to that of FIG. 14 for setting detailed items regarding the copy function is displayed.

FIG. 21 is a drawing for explaining another example of the detail setting screen. In this drawing, an example is depicted in which no image is displayed on a preview 2101 because detailed items have not yet been set. In the drawing, for example, when a setting item 2102 for setting punching is selected, a detail setting screen on which the details of the setting item 2102 are selectable is displayed.

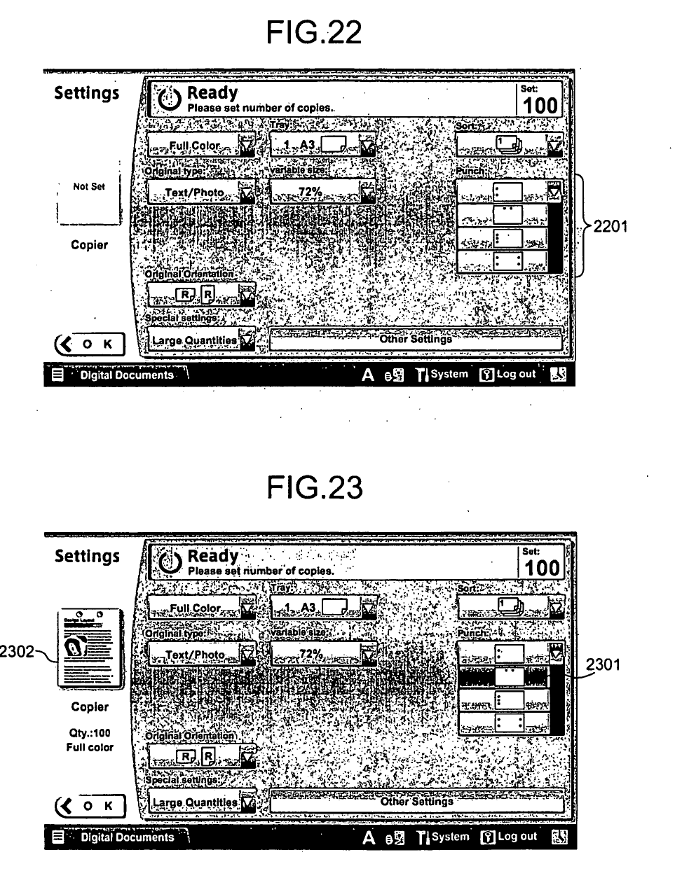

FIG. 22 is a drawing for explaining one example of the detail setting screen in which the details are selectable. As depicted in the drawing, for example, a selection list 2201 from which the position of punched holes is selectable is displayed. Here, when a setting item is changed in the drawing, a preview image indicating the summary of the results obtained with the changed setting is displayed.

FIG. 23 is a drawing for explaining one example of a detail setting screen in which a preview image is displayed. As depicted in the drawing, a preview image 2302 is displayed correspondingly to a setting item 2301 regarding the changed punching. In the preview image 2302, the punched holes are depicted so as to be positioned on an upper portion of the document. Here, as the preview image 2302, an image is displayed on which the setting item 2301 instantaneously selected at the time of selecting the setting item 2301 is reflected.

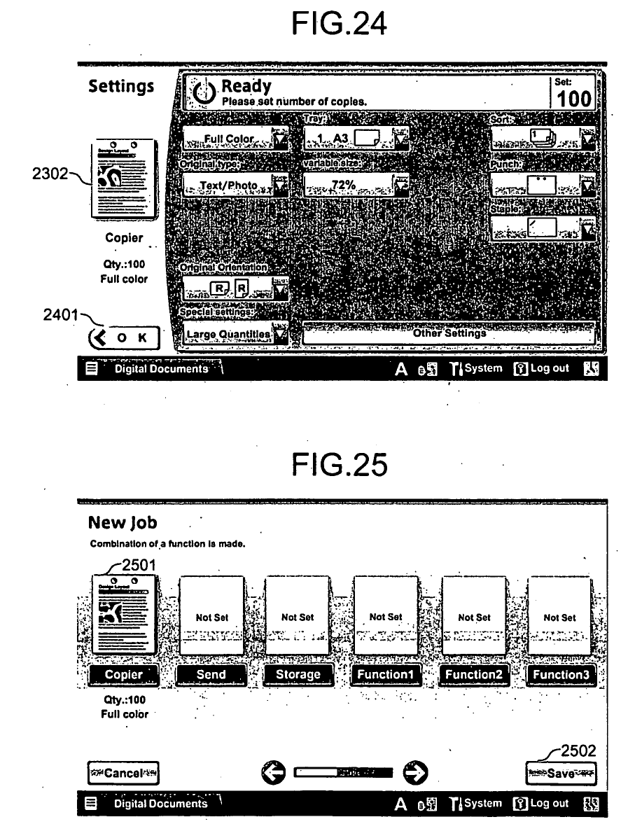

FIG. 24 is a drawing for explaining one example of a detail setting screen after selection of all setting items has been completed. As depicted in the drawing, on the detail setting screen after selection of the setting times, the preview image 2302 is displayed on which all settings are reflected. When an OK button 2401 is selected, a job creation screen on which the newly set function is added is displayed.

FIG. 25 is a drawing for explaining one example of the job creation screen after function addition. As depicted in the drawing, on the job creation screen after a function is added, a preview 2501 indicating the summary of the process result of the added function is displayed. In the drawing, when a Save button 2502 is selected, a name input screen for entering a name of the new job is displayed.

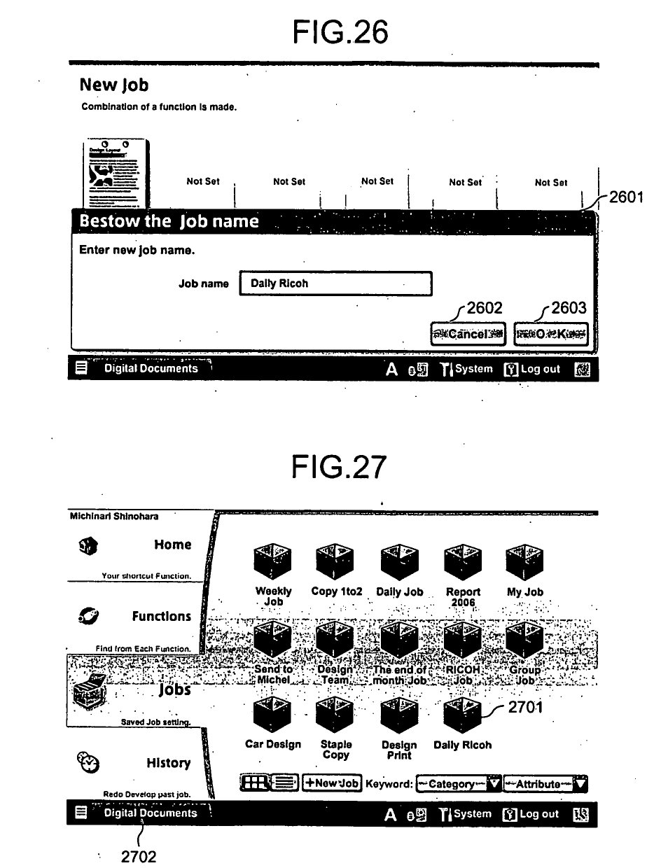

FIG. 26 is a drawing for explaining one example of the name input screen. As depicted in the drawing, on the name input screen, an input area 2601 for entering the name of a job is displayed on a lower portion of the screen. When a Cancel button 2602 is selected, the screen returns to the job creation screen. When an OK button 2603 is selected, a new job is created with the entered name, and the screen then returns to the Job screen.

FIG. 27 is a drawing for explaining one example of the Job screen after a new job is added. In this drawing, the example is depicted in which a job 2701 is added as a new job.

The details about the new job creating process have been explained above. As depicted in the Job screen of FIG. 27, a Digital document button 2702 is displayed on a lower-left portion of the screen.

As with the digital document button 604, the Digital document button 2702 is a button for displaying an eDocuments screen on which a document is specified as an input source. As explained above, the Digital document button 2702 is displayed and selectable on any screen. Details about the eDocuments screen are explained below.

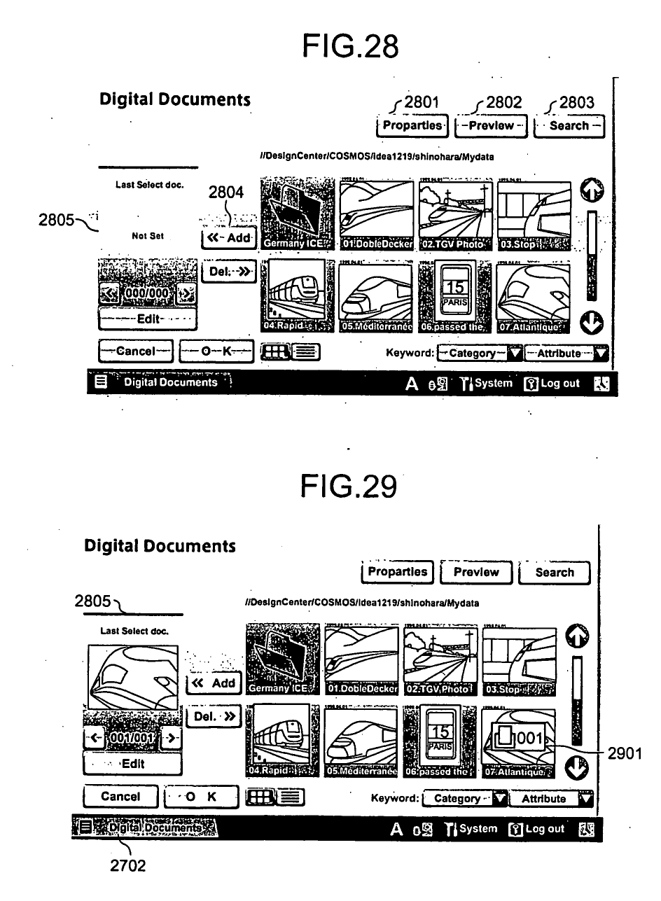

FIG. 28 is a drawing for explaining one example of the eDocuments screen. As depicted in the drawing, on the eDocuments screen, thumbnail images that each can serve as an input source are displayed and selectable by the user.

On the eDocuments screen, in addition to documents stored inside the MFP 1, a document obtainable from an external device by using the communication control unit 126 or the like can be displayed as an input source document.

On an upper portion of the thumbnail images, various buttons are displayed for display of attributes. When a Property button 2801 is selected, a screen (not shown) that displays attributes of the selected document is displayed. When a Preview button 2802 is selected, a screen (not shown) on which a preview image with the selected document image is enlarged is checked is displayed. When a Search button 2803 is selected, a screen (not shown) for searching for an input source document is displayed.

After a thumbnail image is selected, when an Add button 2804 is selected, the selected thumbnail image is displayed in a selected document display area 2805.

FIG. 29 is a drawing for explaining one example of an eDocuments screen after a thumbnail image is added. As depicted in the drawing, after a thumbnail is added, a thumbnail image of the selected document is displayed in the selected document display area 2805. Also, the selected thumbnail image has displayed thereon selection information 2901, which is information indicative of selection.

In the drawing, after a document is selected, a rendering attribute, such as a display color of the Digital document button 2702, is changed. Also, once a document is selected, even if the screen makes a transition to the screen of another function, the Digital document button 2702 is displayed with the changed display color. With this, the user can easily and clearly recognize that the input source document has been selected.

The scaling of the thumbnail images on the eDocuments screen can be changed through a predetermined button operation or the like.

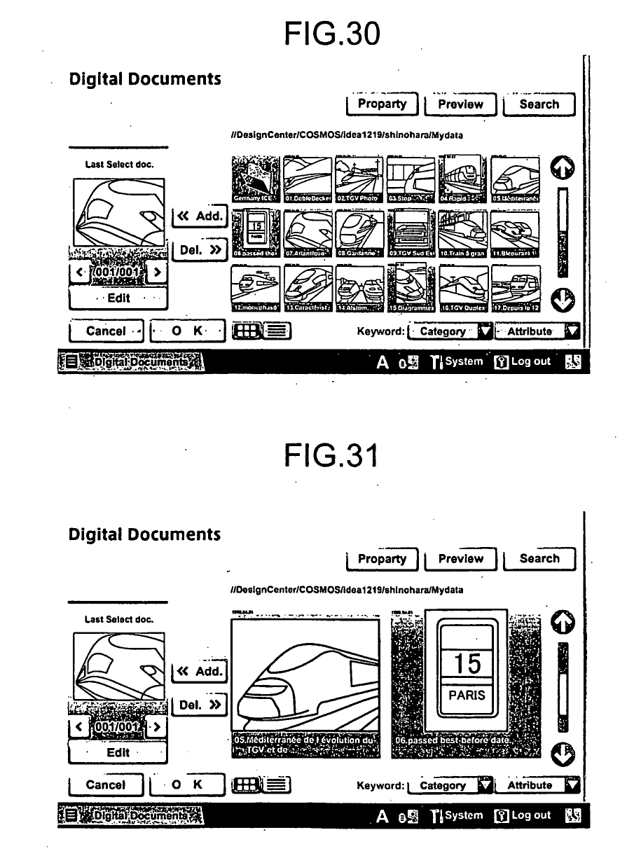

FIG. 30 is a drawing for explaining one example of an eDocuments screen in which thumbnail images are reduced and displayed. As depicted in the drawing, the thumbnail images are displayed as being reduced compared with FIG. 28 or FIG. 29.

FIG. 31 is a drawing for explaining one example of an eDocuments screen in which thumbnail images are enlarged and displayed. As depicted in the drawing, the thumbnail images are enlarged as being reduced compared with FIG. 28 or FIG. 29.

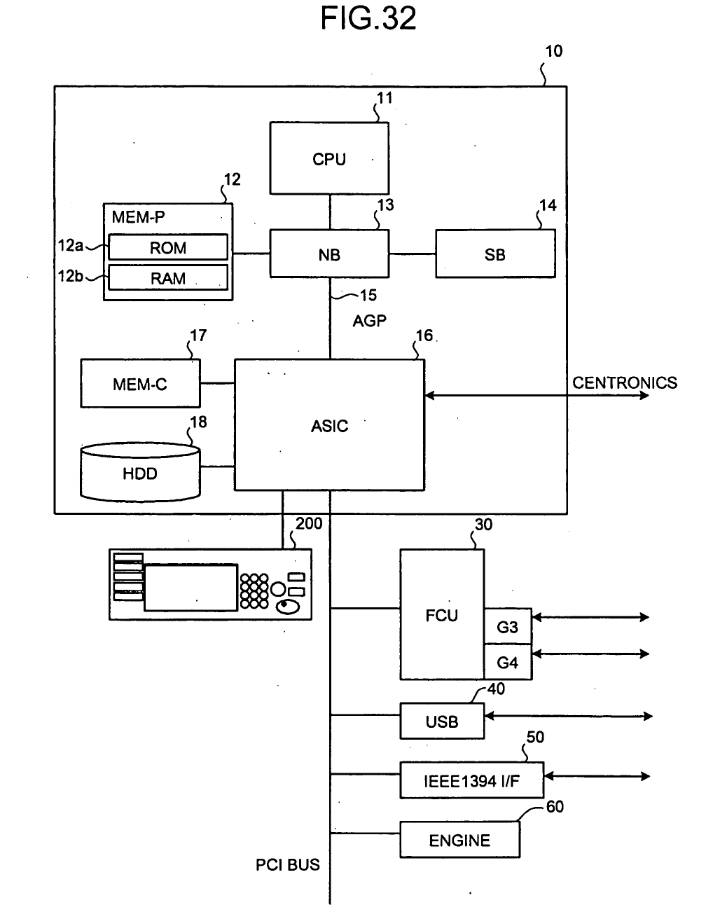

FIG. 32 is a block diagram of a hardware configuration of the MFP according to the first embodiment. As depicted in the drawing, the MFP 1 is configured with a controller 10 and an engine unit 60 being connected to each other via a peripheral component interconnect (PCI) bus. The controller 10 is a controller that controls the MFP 1, rendering, communications, and an input from the operation panel 200. The engine unit 60 is, for example, a printer engine connectable to the PCI bus, and is, for example, a black-and-white plotter, a 1-drum color plotter, a 4-drum color plotter, a scanner, or a facsimile unit. The engine unit 60 includes, in addition to a so-called engine portion, such as a plotter, image processing portions for error diffusion, gamma transformation, and others.

The controller 10 includes a central processing unit (CPU) 11, a Northbridge (NB) 13, a system memory (MEM-P) 12, a Southbridge (SB) 14, a local memory (MEM-C) 17, an application specific integrated circuit (ASIC) 16, and an HDD 18, with the NB 13 and the ASIC 16 being connected therebetween with an Accelerated Graphics Port (AGP) bus 15. Also, the MEM-P 12 further includes a read only memory (ROM) 12a and a RAM 12b.

The CPU 11 performs controls over the MFP 1, includes a chip set formed of the NB 13, the MEM-P 12, and the SB 14, and is connected to other devices via this chip set.

The NB 13 is a bridge for connection of the CPU 11 with the MEM-P 12, the SB 14, and the AGP bus 15, and includes: a memory controller that controls, for example, reading and writing with respect to the MEM-P 12; a PCI master; and an AGP-target.

The MEM-P 12 is a system memory for use as, for example, a memory for storing programs and data, a memory for developing programs and data, or a printer's memory for rendering, and includes the ROM 12a and the RAM 12b. The ROM 12a is a read-only memory for use as a memory for storing programs and data, whilst the RAM 12b is a writable and readable memory for use as, for example, a memory for storing programs, a memory for developing programs and data or a printer's rendering memory.

The SB 14 is a bridge for connection of the NB 13 with PCI devices and peripheral devices. The SB 14 is connected to the NB 13 via the PCI bus. To this PCI bus, a network interface (I/F) unit is also connected, for example.

The ASIC 16 is an integrated circuit (IC) dedicated to image processing, contains hardware components for image processing, and serves as a bridge for connecting the AGP bus 15, the PCI bus, the HDD 18, and the MEM-C 17. The ASIC 16 includes: a PCI target; an AGP master; an arbiter (ARB), which is a core of the ASIC 16; a memory controller that controls the MEM-C 17; a plurality of direct memory access controllers (DMACs) for image data rotation and others by a hardware logic and others; and a PCI unit for data transfer with the engine unit 60 through the PCI bus. A fax control unit (FCU) 30, a universal serial bus (USB) 40, and an Institute of Electrical and Electronics Engineers (IEEE) 1394 I/F 50 are connected to the ASIC 16 via the PCI bus.

The MEM-C 17 is a local memory for use as an image buffer for copying or a coding buffer. The HDD 18 is a storage for storing programs, font data, and forms.

The AGP bus 15 is a bus interface for a graphics accelerator card suggested for increasing the speed of graphic processing, and increases the speed of the graphics accelerator card by directly accessing the MEM-P 12 with a high throughput.

In this manner, the display processing device according to the present invention, a plurality of functions are disposed around the outer perimeter of a predetermined area on the screen. When switching is made among the functions, these functions are rotationally displayed so as to move on the outer perimeter, thereby causing a newly selected function to be displayed at the front. The settings of the functions other than the selected function can be displayed as being reduced so as not to be selectable. With this, it is easy to understand the settings of the functions other than the function currently being processed, thereby increasing the operability of an item setting process.

According to the first embodiment, the MFP executing a display processing device has been explained. However, the apparatus executing the display processing device is not meant to be restricted to an MFP. Thus, in a second embodiment of the present invention, an example of configuration of a display processing device other than an MFP is explained.

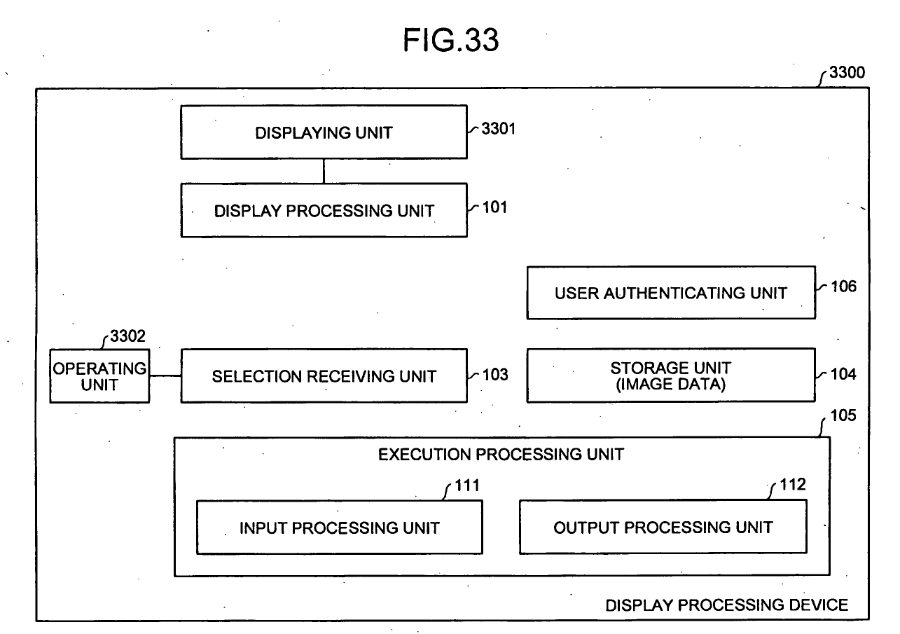

FIG. 33 is a function block diagram of a display processing device 3300 according to the second embodiment. As depicted in the drawing, the display processing device 3300 has a configuration approximately similar to the inside of the application layer 151 of the MFP according to the first embodiment. What is different in the second embodiment is that a displaying unit 3301 and an operating unit 3302 are added in place of the operation panel 200 including the LCD touch panel 220 and the storage unit 104 is provided inside of the application layer 151.

The displaying unit 3301 is a processing unit on which various screens are caused to be displayed by the display processing unit 101. The displaying unit 3301 can be, for example, a liquid crystal touch panel incorporated in the display processing device 3300.

The operating unit 3302 is an interface provided for allowing the user to operate the display processing device 3300. The operating unit 3302 can be any mechanism as long as it is an interface capable of executing selection of each function or setting item.

With an input from the operating unit 3302, the selection receiving unit 103 receives selection of each function or setting item. That is, even when a liquid crystal panel as that according to the first embodiment is provided as the displaying unit 3301, the panel does not have to be a liquid crystal touch panel allowing inputs through a touch of a finger of the user or the like.

Examples of the apparatus having incorporated therein the display processing device 3300, for example, an image forming apparatus and an audiovisual (AV) devices in which music data can be stored for output to another device, reproduction, or others. That is, the device may be arbitrary as long as it has an input function, an output function, and other functions, it can causes a display on a displaying unit, such as a liquid crystal panel, provided in the device, and it includes an interface having a liquid crystal touch panel, a plurality of buttons, or the like for executing selection of a function or selection of a setting item.

In other examples, the display processing device 3300 may be incorporated in a general-purpose personal computer (PC) or a car navigation apparatus. In the case of the PC, selection of a function or selection of a setting item can be executed with an input device generally used, such as a keyboard or a mouse.

Also, the display processing device 3300 can be incorporated in, for example, a device for portable use including a displaying unit having a necessary and sufficient size for displaying a plurality of functions or setting items and an interface. For example, a portable terminal provided with a liquid crystal touch panel can be thought, such as a PDA o a portable game machine.

Even in such a portable device with insufficient displaying unit and interface, with the application of the method according to the embodiment, the settings can be easily recognized, thereby increasing the operability.

Also, as with the first embodiment, a touch panel, for example, may be used as the operating unit of the display processing device. For example, in an apparatus provided with a touch panel, a plurality of functions or setting items are displayed on the displaying unit, and selection of a function or the like displayed by the user pressing the touch panel can be received. In this manner, even in an apparatus in which an input interface is limited, the setting items and preview information on which the setting items are reflected are displayed on the same screen. With this, the settings can be easily checked, thereby increasing the operability.

Note that the display processing program executed on the display processing device according to the embodiments is provided as being previously incorporated in a ROM or the like.

The display processing program executed on the display processing device according to the embodiments may be configured to be provided as being recorded as a file in an installable format or an executable format on a computer-readable recording medium, such as a compact disk-read only memory (CD-ROM), a flexible disk (FD), a compact Disk-recordable (CD-R), or a digital versatile disk (DVD).

Furthermore, the display processing program executed on the display processing device according to the embodiments may be configured to be provided as being stored on a computer connected to a network, such as the Internet, and then being downloaded through the network. Also, the display processing program executed on the display processing device according to the embodiments may be provided or distributed through a network, such as the Internet.

The display processing program executed on the display processing device according to the embodiments has a module configuration including each of the components explained above (the display processing unit, the selection receiving unit, the execution processing unit, and the user authenticating unit). As actual hardware, with the CPU (processor) reading the image processing program from the ROM for execution, each unit explained above is loaded onto a main storage device, thereby generating each unit on the main storage device.

As describe above, according to one aspect of the present invention, on the screen on which a setting item is selected, preview information indicating the result of image processing using the selected setting item can be displayed. Therefore, an effect can be achieved such that the settings can be easily understood, thereby increasing the operability of an item setting process.

Furthermore, according to another aspect of the present invention, a touch input can be made on the display screen. Therefore, an effect can be achieved such that the operability of the item setting process can be further increased.

Moreover, according to still another aspect of the present invention, an input can be made through an input unit, such as a mouse or keyboard, on the display screen. Therefore, an effect can be achieved such that the operability of the item setting process can be further increased.

Furthermore, according to still another aspect of the present invention, preview information can be displayed for each of the image processes. Therefore, an effect can be achieved such that, even when a plurality of image processes are concurrently executed, the settings can be easily understood.

Moreover, according to still another aspect of the present invention, the screen on which a sub-setting item can be displayed on a screen different from the screen on which an upper setting item. Therefore, an effect can be achieved such that the user can easily understand the item currently being set, and even many sub-setting items can be displayed on the screen.

Furthermore, according to still another aspect of the present invention, on the screen on which a sub-setting item is displayed, information regarding the corresponding upper setting item can be displayed. Therefore, an effect can be achieved such that the user can clearly understand which upper setting item corresponds to the sub-setting item being set.

Moreover, according to still another aspect of the present invention, identification information of the setting items can be displayed in an at-a-glance format. Therefore, an effect can be achieved such that the information can be easily checked, thereby increasing the operability of the item setting process.

Furthermore, according/to still another aspect of the present invention, a setting item can be displayed in an icon format representing the setting item. Therefore, an effect can be achieved such that the information can be easily checked, thereby increasing the operability of the information selecting process.

Moreover, according to still another aspect of the present invention, an attribute representing the meaning of the setting item can be specified. Therefore, an effect can be achieved such that a display of the setting item according to the specified attribute can be made.

Furthermore, according to still another aspect of the present invention, the setting item having the selected attribute can be displayed. Therefore, an effect can be achieved such that the setting items can be narrowed down, thereby increasing the operability of the item setting process.

Moreover, according to still another aspect of the present invention, attributes having a hierarchical structure can be specified for each layer. Therefore, an effect can be achieved such that the setting items can be narrowed down in more detail.

Furthermore, according to still another aspect of the present invention, the selection screen of information to be processed can be displayed. Therefore, an effect can be achieved such that the operability of a predetermined entire process including the information selecting process can be increased.

Moreover, according to still another aspect of the present invention, specification information about, for example, buttons for displaying the selection screen, can always be displayed. Therefore, an effect can be achieved such that the operability of information selecting process can be increased.

Furthermore, according to still another aspect of the present invention, a rendering attribute of the specification information about, for example, the buttons after obtaining the information to be processed, can be changed on the selection screen. Therefore, an effect can be achieved such that the user can easily understand that the information has been selected.

Moreover, according to still another aspect of the present invention, the progress of a predetermined process using the selected setting item can be displayed. Therefore, an effect can be achieved such that the user can clearly understand the process state.

Furthermore, according to still another aspect of the present invention, preview information of a plurality of process concurrently being executed can be displayed together with the progress. Therefore, an effect can be achieved such that the user can clearly understand the state of the processes concurrently being executed.

Moreover, according to still another aspect of the present invention, on a screen on which a setting item regarding an image forming process is selected, preview information indicating the result of the image process using the selected setting item is displayed. Therefore, an effect can be achieved such that the settings can be easily understood, thereby increasing the operability of the item setting process.

Furthermore, according to still another aspect of the present invention, an effect can be achieved such that a computer can be caused to perform any one of the methods according to the present invention.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A display processing device comprising:
a display processing unit that displays a setting item for an image processing and preview information indicating an overview of a result of the image processing using the setting item on a screen of a displaying unit; and
a selection receiving unit that receives a selection of an arbitrary setting item from among setting items displayed on the screen, wherein
the display processing unit changes the preview information based on an overview of a result of the image processing using a setting item changed by a user or a setting item for which the selection is received, and displays changed preview information on the screen.

2. The display processing device according to claim 1, wherein when a plurality of image processings are executed in parallel, the display processing unit displays the preview information for each of the image processings on the screen.

3. The display processing device according to claim 1, wherein when a sub-setting item that is associated with the setting item for which the selection is received is present, the display processing unit displays the sub-setting item on a screen different from the screen on which the setting item is displayed.

4. The display processing device according to claim 3, wherein the display processing unit displays information on the setting item that is associated with the sub-setting item on the screen on which the sub-setting item is displayed.

5. The display processing device according to claim 1, wherein
the display processing unit further displays a predetermined attribute representing a meaning of the setting item on the screen in a selectable manner, and
the selection receiving unit further receives a selection of an arbitrary attribute from among attributes displayed on the screen.

6. The display processing device according to claim 5, wherein when the selection receiving unit receives the selection of the attribute, the display processing unit displays the setting item having the attribute for which the selection is received on the screen.

7. The display processing device according to claim 1, wherein the display processing unit further displays a selection screen for selecting information on the image processing to be performed by using the setting item for which the selection is received on the screen.

8. The display processing device according to claim 1, wherein the display processing unit further displays a progress of the image processing performed by using the setting item for which the selection is received on the screen.

9. A display processing method comprising:
displaying a setting item for an image processing and preview information indicating an overview of a result of the image processing using the setting item on a screen of a displaying unit; and
receiving a selection of an arbitrary setting item from among setting items displayed on the screen, wherein
the displaying includes
changing the preview information based on an overview of a result of the image processing using a setting item changed by a user or a setting item for which the selection is received, and
displaying changed preview information on the screen.

10. The display processing method according to claim 9, wherein when a plurality of image processings are executed in parallel, the displaying includes displaying the preview information for each of the image processings on the screen.

11. The display processing method according to claim 9, wherein when a sub-setting item that is associated with the setting item for which the selection is received is present, the displaying includes displaying the sub-setting item on a screen different from the screen on which the setting item is displayed.

12. The display processing method according to claim 11, wherein the displaying includes displaying information on the setting item that is associated with the sub-setting item on the screen on which the sub-setting item is displayed.

13. The display processing method according to claim 9, wherein
the displaying includes displaying a predetermined attribute representing a meaning of the setting item on the screen in a selectable manner, and
the receiving includes receiving a selection of an arbitrary attribute from among attributes displayed on the screen.

14. The display processing method according to claim 13, wherein when the selection of the attribute is received, the displaying includes displaying the setting item having the attribute for which the selection is received on the screen.

15. The display processing method according to claim 9, wherein the displaying includes displaying a selection screen for selecting information on the image processing to be performed by using the setting item for which the selection is received on the screen.

16. The display processing method according to claim 15, wherein in the displaying includes displaying specification information for specifying a display of the selection screen on the screen constantly in a selectable manner.

17. The display processing method according to claim 15, wherein
the receiving includes receiving a selection of at least one of pieces of the information displayed on the selection screen, and
when the selection of the information is received, the displaying includes displaying the specification information with a rendering attribute different from a rendering attribute before the selection of the information is received.

18. The display processing method according to claim 9, wherein the displaying includes displaying a progress of the image processing performed by using the setting item for which the selection is received on the screen.

19. The display processing method according to claim 18, wherein when a plurality of image processings are executed in parallel, the displaying includes displaying the preview information for each of the image processings and progresses of the image processings on the preview information.

20. A computer program product comprising a computer-usable medium having computer-readable program codes embodied in the medium that when executed cause a computer to execute:
displaying a setting item for an image processing and preview information indicating an overview of a result of the image processing using the setting item on a screen of a displaying unit; and
receiving a selection of an arbitrary setting item from among setting items displayed on the screen, wherein
the displaying includes
changing the preview information based on an overview of a result of the image processing using a setting item changed by a user or a setting item for which the selection is received, and
displaying changed preview information on the screen.
